(19) United States
(12) Patent Application Publication
(10) Pub. No.: US 2024/0145573 A1
(43) Pub. Date: May 2, 2024

(54) SEMICONDUCTOR DEVICE AND METHOD OF MANUFACTURING THE SAME

(71) Applicant: Samsung Electronics Co., Ltd., Suwon-si (KR)

(72) Inventors: Ilgyou Shin, Suwon-si (KR); Hyunho Noh, Suwon-si (KR); Sanghyun Hong, Suwon-si (KR); Sangyong Kim, Suwon-si (KR); HyungJun Kim, Suwon-si (KR)

(21) Appl. No.: 18/382,166

(22) Filed: Oct. 20, 2023

(30) Foreign Application Priority Data
Oct. 26, 2022 (KR) 10-2022-0139055

(51) Int. Cl. H01L 29/51; H01L 27/088; H01L 29/06; H01L 29/423; H01L 29/775; H01L 29/786

(52) U.S. Cl. CPC H01L 29/517; H01L 27/088; H01L 29/0673; H01L 29/42392; H01L 29/775; H01L 29/78696

(57) ABSTRACT

A semiconductor device includes a first transistor on a first region of a substrate, and a second transistor on a second region of the substrate. The first transistor includes a first gate insulating layer including a first interfacial insulating layer, a first lower high-κ dielectric layer, and a first composite dielectric layer, sequentially stacked on each of first semiconductor channel layers. The second transistor includes a second gate insulating layer including a second interfacial insulating layer, a second lower high-κ dielectric layer, a second composite dielectric layer, and a second upper high-κ dielectric layer, sequentially stacked on each of second semiconductor channel layers. The first and the second lower high-κ dielectric layers include a first metal element, the second upper high-κ dielectric layer includes a second metal element, and the first and the second composite dielectric layers include both of the first and the second metal elements.

### CROSS-REFERENCE TO RELATED APPLICATION(S)

This application claims priority under 35 USC 119(a) to Korean Patent Application No. 10-2022-0139055 filed on Oct. 26, 2022 in the Korean Intellectual Property Office, the disclosure of which is incorporated herein by reference in its entirety.

### BACKGROUND

The present inventive concept relates to a semiconductor device and a method of manufacturing the same.

The semiconductor device includes an integrated circuit composed of a Metal Oxide Semiconductor Field Effect Transistor (MOSFET). As the size and design rules of semiconductor devices are gradually reduced, the scaling down of MOSFETs is also gradually accelerating. Operating characteristics such as short-channel effect, parasitic capacitance, and off-state leakage current may deteriorate as the size of the MOSFET is reduced. Accordingly, various methods of forming a semiconductor device with better performance while overcoming limitations due to high integration of the semiconductor device are being studied.

### SUMMARY

Example embodiments provide a semiconductor device having improved electrical characteristics.

Example embodiments provide a method of manufacturing a semiconductor device having improved electrical characteristics.

According to example embodiments, a semiconductor device includes a first transistor on a first region of a substrate and a second transistor on a second region of the substrate. The first transistor includes first semiconductor channel layers spaced apart from each other and stacked on the first region of the substrate in a vertical direction perpendicular to an upper surface of the substrate, a first gate insulating layer surrounding the first semiconductor channel layers, and including a first interfacial insulating layer, a first lower high-κ dielectric layer containing a first metal element, and a first composite dielectric layer containing the first metal element and a second metal element different from the first metal element, the first interfacial insulating layer the first lower high-κ dielectric layer and the first composite dielectric layer sequentially stacked on each of the first semiconductor channel layers, and a first gate electrode on the first gate insulating layer. The second transistor includes second semiconductor channel layers spaced apart from each other and stacked on a second region of the substrate in the vertical direction, a second gate insulating layer surrounding the second semiconductor channel layers, and including a second interfacial insulating layer, a second lower high-κ dielectric layer containing the first metal element, a second composite dielectric layer containing the first metal element and the second metal element, and a second upper high-κ dielectric layer containing the second metal element, the second interfacial insulating layer, the second lower high-κ dielectric layer, the second composite dielectric layer, and the second upper high-κ dielectric layer sequentially stacked on each of the second semiconductor channel layers, and a second gate electrode on the second gate insulating layer.

According to example embodiments, a semiconductor device includes a substrate including an active pattern extending in a first direction; semiconductor channel layers spaced apart from each other and stacked on the active pattern in a direction perpendicular to an upper surface of the substrate; a gate structure on the substrate, extending in a second direction, intersecting the semiconductor channel layers, and surrounding the semiconductor channel layers; and a source/drain region disposed on the active pattern on at least one side of the gate structure and connected to the semiconductor channel layers. The gate structure surrounds the semiconductor channel layers and includes a gate insulating layer and a gate electrode disposed on the gate insulating layer. The gate insulating layer includes an interfacial insulating layer, a lower high-κ dielectric layer containing a first metal element, a composite dielectric layer containing the first metal element and a second metal element, different from the first metal element, and an upper high-κ dielectric layer containing the second metal element, sequentially disposed on the semiconductor channel layers.

According to example embodiments, a semiconductor device includes a substrate including a first region and a second region; a first active pattern on the first region of the substrate; a first gate insulating layer including a first interfacial insulating film, a first lower high-κ dielectric film, and a first composite dielectric film, sequentially stacked on the first active pattern; a first gate electrode on the first gate insulating layer; a second active pattern on the second region of the substrate; and a second gate insulating layer including a second interfacial insulating film, a second lower high-κ dielectric film, and a second composite dielectric film, and a second upper high-κ dielectric film, sequentially stacked on the second active pattern. Each of the first and the second lower high-κ dielectric films includes a first metal element, the second upper high-κ dielectric films includes a second metal element, and each of the first and the second composite dielectric films includes both of the first and the second metal elements.

According to example embodiments, a method of manufacturing a semiconductor device includes forming a stack of first semiconductor channel layers and a stack of second semiconductor channel layers in a first region and a second region of a substrate, respectively; forming first and second interfacial insulating films surrounding the first and second semiconductor channel layers respectively; forming first and second lower high-κ dielectric layers including a first metal element on the first and second interfacial insulating layers, respectively; forming a second upper high-κ dielectric layer including a second metal element on the second lower high-κ dielectric layer; and forming a first composite dielectric layer including the first metal element on the first lower high-κ dielectric layer; and forming a second composite dielectric layer including the second metal element between the second lower high-κ dielectric layer and the second upper high-κ dielectric layer. The first and second metal elements may be different from each other.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a plan view illustrating a semiconductor device according to an exemplary embodiment.

FIG. 2A is cross-sectional views of a first region of the semiconductor device illustrated in FIG. 1 taken along lines I1-I1′ and II1-II1′ according to an exemplary embodiment.

FIG. 2B is cross-sectional views of the second region of the semiconductor device illustrated in FIG. 1 taken along lines I2-I2′ and II2-II2′ according to an exemplary embodiment.

FIGS. 3A and 3B are partially enlarged views illustrating a portion A1 of FIG. 2A and a portion A2 of FIG. 2B, respectively, according to an exemplary embodiment.

FIGS. 4A to 4E are perspective views illustrating some processes of a method of manufacturing a semiconductor device according to exemplary embodiments.

FIGS. 5A and 5B are cross-sectional views illustrating some processes (a process of removing a dummy gate structure) of a method of manufacturing a semiconductor device according to an exemplary embodiment.

FIGS. 6A to 6E are cross-sectional views illustrating some processes (a gate insulating layer forming process) of a method of manufacturing a semiconductor device according to an exemplary embodiment.

FIGS. 7A and 7B are partially enlarged views illustrating an annealing process of FIG. 6C according to an exemplary embodiment.

FIG. 8 is a graph illustrating a concentration distribution of a composite dielectric film formed by annealing and a metal element around it according to an exemplary embodiment.

FIG. 9 is a plan view illustrating a semiconductor device according to an exemplary embodiment.

FIG. 10A is cross-sectional views of a first region of the semiconductor device illustrated in FIG. 9 taken along lines I1-I1′ and II1-II1′ according to an exemplary embodiment.

FIG. 10B is cross-sectional views of the second region of the semiconductor device illustrated in FIG. 9 taken along lines I2-I2′ and II2-II2′ according to an exemplary embodiment.

### DETAILED DESCRIPTION

Hereinafter, example embodiments will be described with reference to the accompanying drawings.

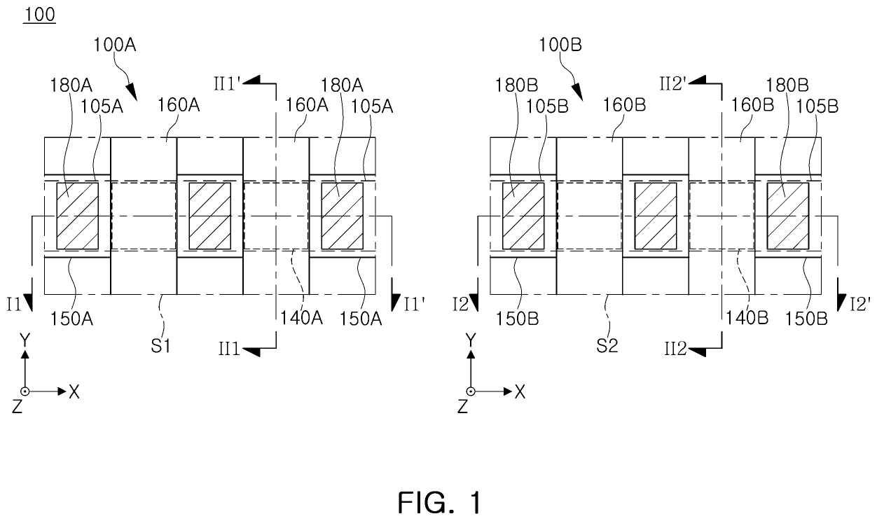

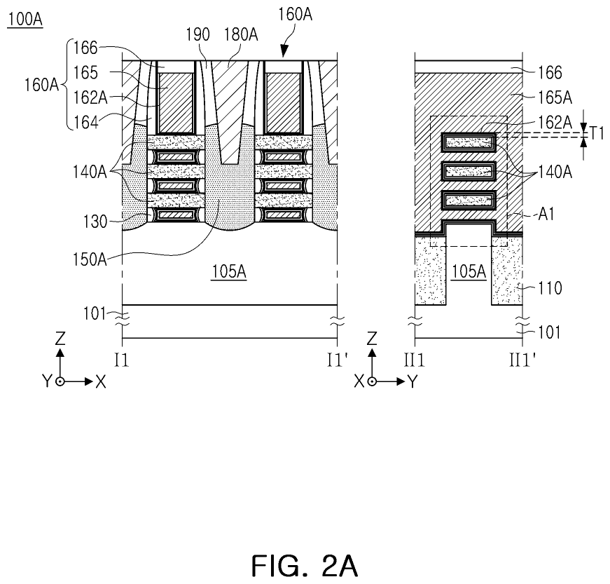

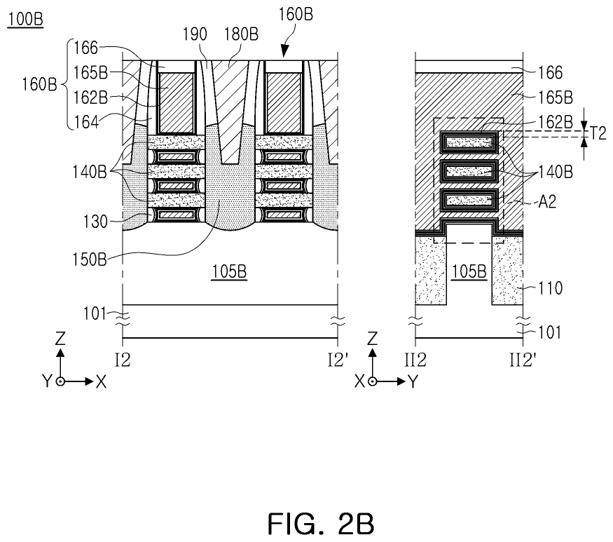

FIG. 1 is a plan view illustrating a semiconductor device according to an exemplary embodiment, and FIG. 2A is cross-sectional views of a first region of the semiconductor device illustrated in FIG. 1, taken along lines I1-I1′ and FIG. 2B is cross-sectional views of a second region of the semiconductor device illustrated in FIG. 1, taken along lines I2-I2′ and II2-II2′.

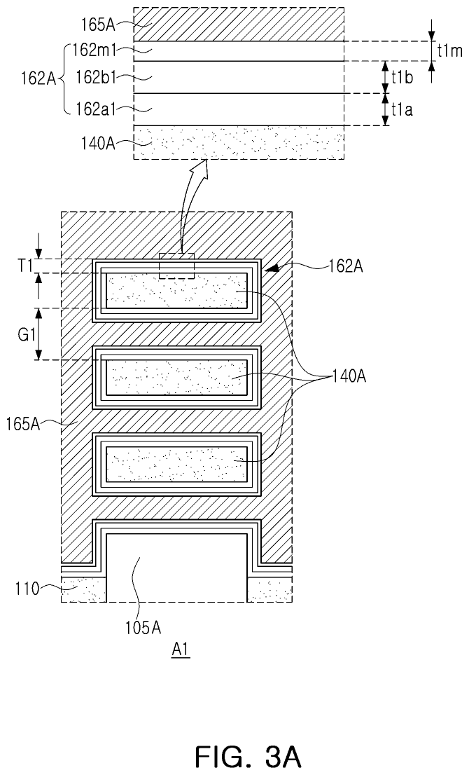

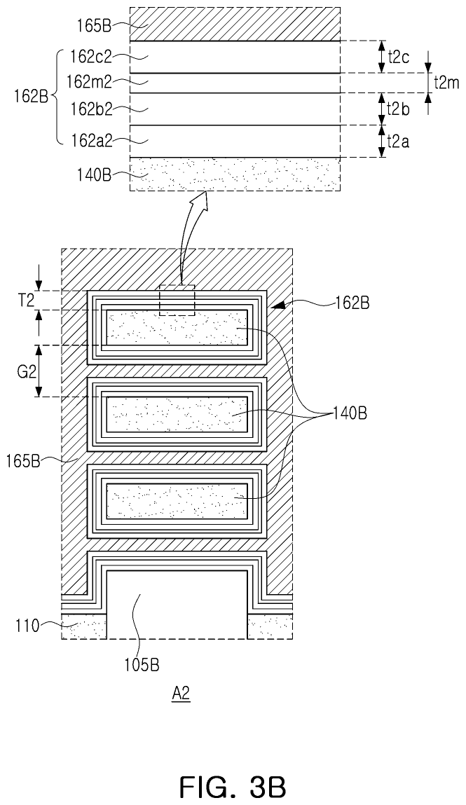

Referring to FIGS. 1, 2A, and 2B, a semiconductor device 100 according to an example embodiment includes a substrate 101, a first transistor 100A disposed on a first region S1 of the substrate 101, and a second transistor 100B disposed on a second region S2 of the substrate 101. The first transistor 100A is a device for fast operation and has a relatively thin first gate insulating layer 162A, and the second transistor 100B is a device for high voltage resistance and high reliability and has a relatively thick second gate insulation layer 162B. A stack of dielectric layers constituting the first and second gate insulating layers 162A and 162B will be described later with reference to FIGS. 3A and 3B.

Referring to FIGS. 1 and 2A, the first transistor 100A includes a first active pattern 105A extending in a first direction (e.g., X-direction) on the first region S1 of the substrate 101, first semiconductor channel layers 140A disposed on the first active pattern 105A, and a first gate structure 160A extending in a second direction (e.g., Y-direction) crossing the first active pattern 105A. The first semiconductor channel layers 140A are spaced apart from each other in a direction (e.g., Z-direction) perpendicular to the upper surface of the substrate 101 on the first active pattern 105A. In addition, the first transistor 100A may further include first source/drain regions 150A disposed on both sides of the first gate structure 160A and contacting both side surfaces of the first semiconductor channel layers 140A, respectively, and first contacts 180A connected to the first source/drain regions 150A. For example, the first transistor 100A may be a gate-all-around type field effect transistor formed by the first semiconductor channel layers 140A, the first source/drain regions 150A, and the first gate structure 160A, for example, a multi-bridge channel field effect transistor (MBCFET™).

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact.

Similarly, referring to FIGS. 1 and 2B, the second transistor 100B includes a second active pattern 105B extending in a first direction (e.g., X-direction) on the second region S2 of the substrate 101, second semiconductor channel layers 140B disposed on the second active pattern 105B, and a second gate structure 160B extending in a second direction (e.g., Y-direction) crossing the second active pattern 105B. The second semiconductor channel layers 140B are spaced apart from each other in a direction perpendicular to the upper surface of the substrate 101 (e.g., in the Z-direction) on the second active pattern 105B. In addition, the second transistor 100B may further include second source/drain regions 150B disposed on both sides of the second gate structure 160B and contacting both side surfaces of the second semiconductor channel layers 140B, respectively, and second contacts 180B connected to the second source/drain regions 150B. For example, the second transistor 100B may be a gate-all-around type field effect transistor formed by the second semiconductor channel layers 140B, the second source/drain regions 150B, and the second gate structure 160B, for example, a multi-bridge channel field effect transistor (MBCFET™).

In an example embodiment, the first and second active patterns 105A and 105B extend in a first direction (e.g., X-direction) and protrude in a third direction (e.g., Z-direction). Herein, for convenience of description, the terms of “active patterns,” “active fins,” and “active regions” may be used interchangeably. Upper ends of the first and second active patterns 105A and 105B may protrude from the upper surface of a device isolation layer 110 to a predetermined height. For example, the substrate 101 may be a semiconductor substrate such as a silicon substrate or a germanium substrate or a silicon-on-insulator (SOI) substrate. The device isolation layer 110 may be disposed on the substrate 101 to define the first and second active patterns 105A and 105B. The device isolation layer 110 may be disposed on the substrate 101 to cover the side surfaces of the active patterns 105A and 105B of the substrate 101. The device isolation layer 110 may include, for example, an oxide film, a nitride film, or a combination thereof. Herein, for convenience of description, the terms of the “film” and the “layer” may be used interchangeably. The device isolation layer 110 may be formed by a shallow trench isolation (STI) process. In some embodiments, the device isolation layer 110 may further include a region extending deeper into the substrate 101 (e.g., deep trench isolation (DTI)). The device isolation layer 110 may be formed to expose upper regions of the first and second active patterns 105A and 105B. In some embodiments, the device isolation layer 110 may have a curved upper surface having a higher level as it is closer to the first and second active patterns 105A and 105B.

As described above, the first semiconductor channel layers 140A are stacked on the first active pattern 105A while being spaced apart from each other by a first distance G1 (see FIG. 3A) in the vertical direction (e.g., the Z-direction). Similarly, the second semiconductor channel layers 140B are stacked on the second active pattern 105B while being spaced apart from each other by a second distance G2 (see FIG. 3B) in the vertical direction (e.g., the Z-direction). The first semiconductor channel layers 140A and the second semiconductor channel layer 140B may be formed through the same process. The thickness of the first semiconductor channel layer 140A is substantially the same as that of the second semiconductor channel layer 140B, and the first distance G1 may be substantially the same as the second distance G2 (see FIGS. 3A and 3B). In some embodiments, each of the first and second distances G1 and G2 may be 150 Å or less, for example, 100 Å or less. Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

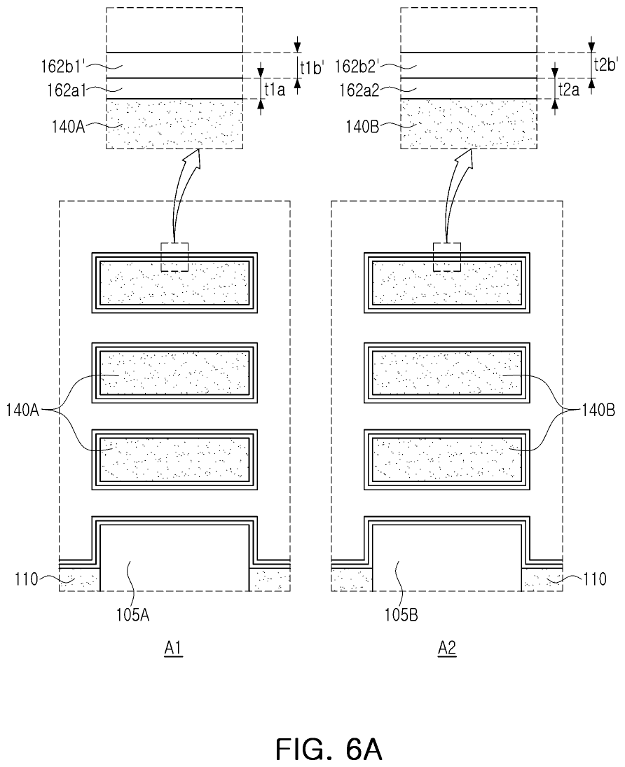

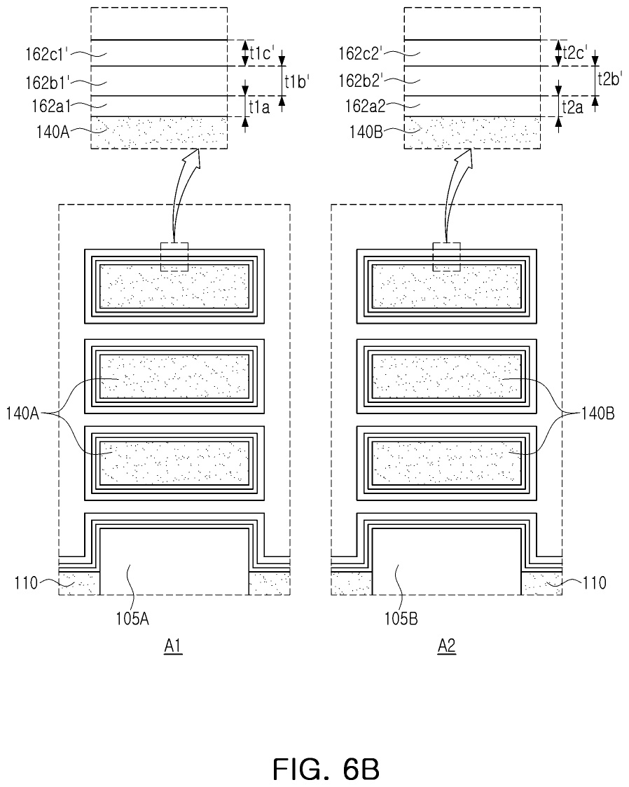

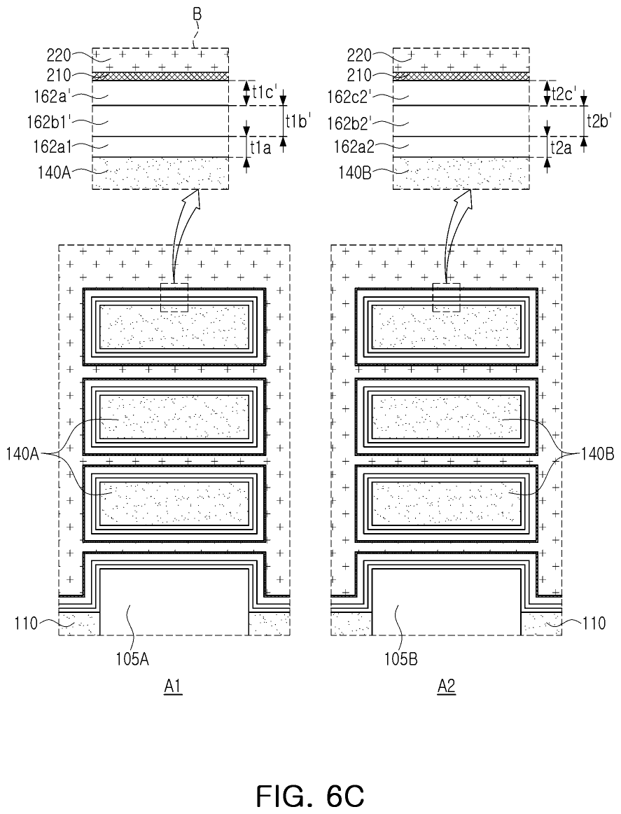

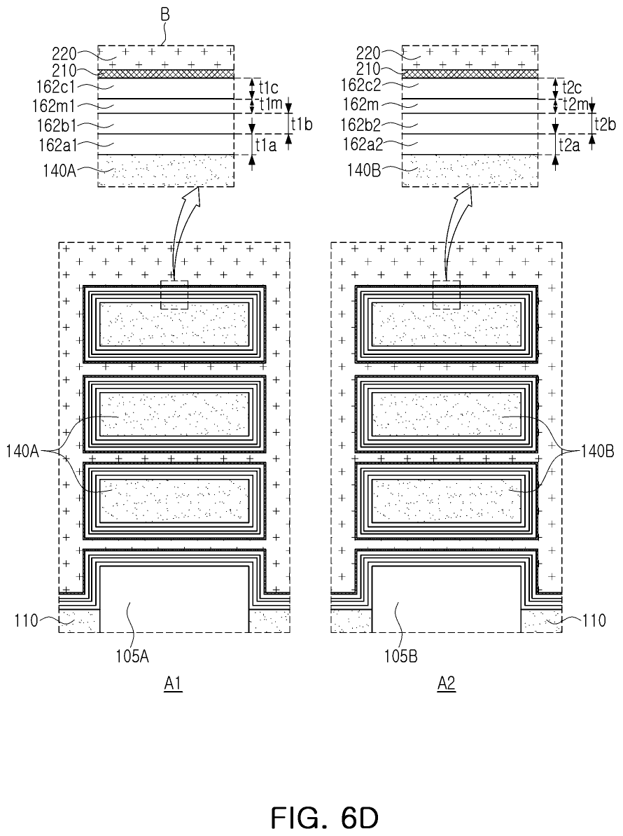

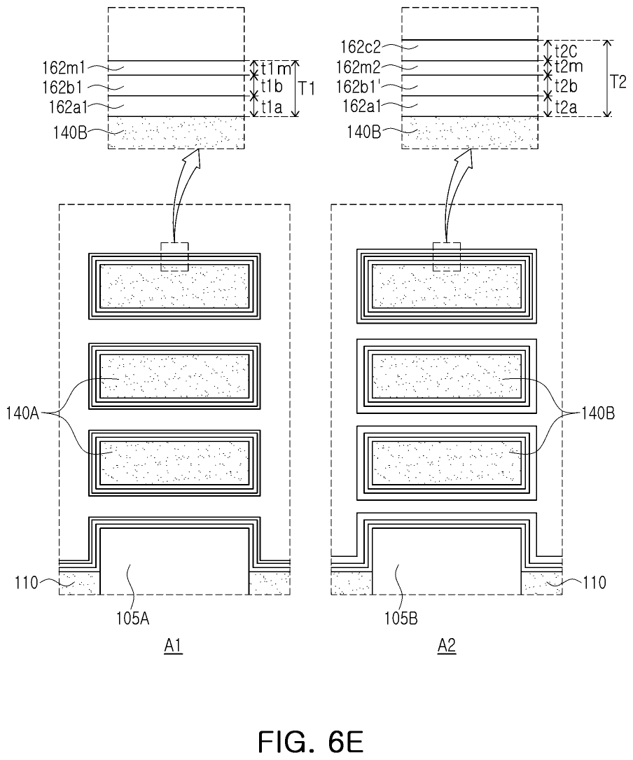

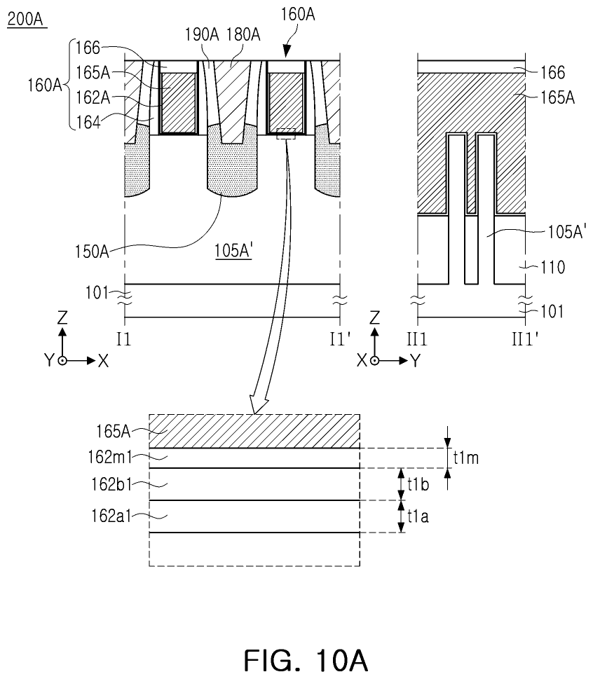

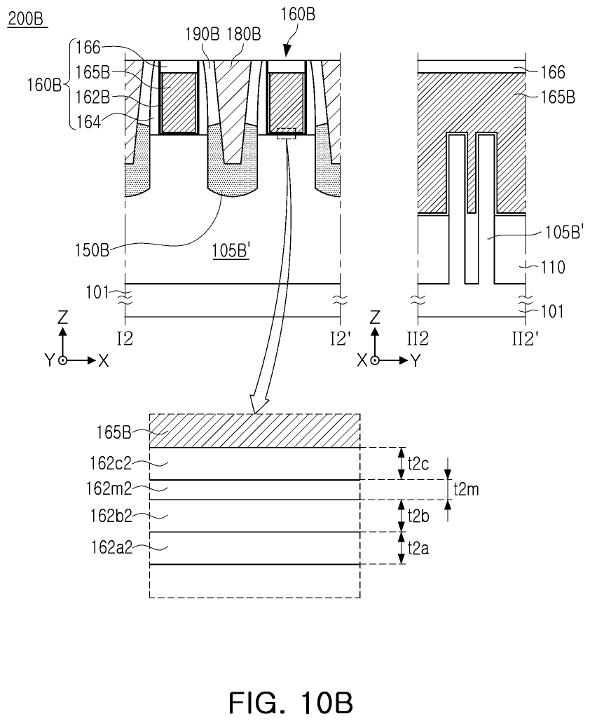

Each of the first semiconductor channel layers 140A and each of the second semiconductor channel layers 140B may include a semiconductor material capable of providing a channel region. For example, each of the first semiconductor channel layers 140A and each of the second semiconductor channel layers 140B may include at least one of silicon (Si), silicon germanium (SiGe), and germanium (Ge). The first and second semiconductor channel layers 140A and 140B may be formed of, for example, the same material as that of the substrate 101. In some embodiments, a region of the first and second source/drain regions adjacent to the first and second semiconductor channel layers 140A and 140B may include an impurity region. Since such an impurity region may cause a short channel effect (SCE), preparation for this may be required. In this embodiment, each of the first and second semiconductor channel layers 140A and 140B is illustrated as three, but the number and shape may be variously changed (see FIGS. 6A to 6E, 10A and 10B).

Referring to FIG. 2A, the first gate structure 160A includes a first gate electrode 165A extending in a second direction (e.g., Y-direction) and surrounding the first semiconductor channel layers 140A, and a first gate insulating layer 162A disposed between the first gate electrode 165A and the first semiconductor channel layers 140A. The first gate structure 160A further may include gate spacers 164 disposed on side surfaces of the first gate electrode 165A and a gate capping layer 166 disposed on the first gate electrode 165A.

Similarly, referring to FIG. 2B, the second gate structure 160B includes a second gate electrode 165B extending in a second direction (e.g., Y-direction) and surrounding the second semiconductor channel layers 140B, and a second gate insulating layer 162B disposed between the second gate electrode 165B and the second semiconductor channel layers 140B. The second gate structure 160B further includes gate spacers 164 disposed on side surfaces of the second gate electrode 165B and a gate capping layer 166 disposed on the second gate electrode 165B.

In this embodiment, the first transistor 100A is a device for fast calculation and may constitute a logic circuit, and the second transistor 100B is a device having high voltage resistance and may constitute a peripheral circuit.

FIGS. 3A and 3B are partially enlarged views illustrating a portion A1 of FIG. 2A and a portion A2 of FIG. 2B, respectively.

Referring to FIGS. 3A and 3B, the first gate insulating layer 162A of the first transistor 100A may have a relatively thin first thickness T1, and the second gate insulating layer 162B of the second transistor 100B may have a second thickness T2 greater than the first thickness T1.

The second thickness T2 of the second gate insulating layer 162B may be less than at least half the second distance G2, such that a space in which the second gate electrode 165B may be interposed may remain between the second semiconductor channel layers 140B. In some embodiments, the second thickness T2 may be 50 Å or less, for example, 40 Å or less.

The first gate insulating layer 162A may surround the first semiconductor channel layers 140A, respectively, and the second gate insulating layer 162B may surround the second semiconductor channels 140B, respectively. In some embodiments, the first and second gate insulating layers 162A and 162B may have a portion disposed on the protruding surfaces of the first and second active patterns 105A and 105B and extending on the upper surface of the device isolation layer 110 in the second direction (e.g., the Y-direction).

The first gate insulating layer 162A may include a first interfacial insulating layer 162a1, a first lower high-κ dielectric layer 162b1, and a first composite dielectric layer 162m1 sequentially stacked on the surface of each of the first semiconductor channel layers 140A. The second gate insulating layer 162B may further include a second upper high-κ dielectric layer 162c2 on the same dielectric layer stack as the first gate insulating layer 162A. In detail, the second gate insulating layer 162B may include a second interfacial insulating layer 162a2, a second lower high-κ dielectric layer 162b2, a second composite dielectric layer 162m2 and the second upper high-κ dielectric layer 162c2 sequentially stacked on respective surfaces of the second semiconductor channel layers 140B.

The first interfacial insulating layer 162a1 may include the same dielectric material as the second interfacial insulating layer 162a2. For example, each of the first and second interfacial insulating layers 162a1 and 162a2 may include or be formed of silicon oxide or silicon oxynitride. The first and second interfacial insulating layers 162a1 and 162a2 may have substantially the same thickness (t1a=t2a). For example, the thicknesses t1a and t2a of the first and second interfacial insulating layers 162a1 and 162a2 may be in the range of 5 Å to 10 Å, respectively.

The first and second lower high-κ dielectric layers 162b1 and 162b2 and the second upper high-κ dielectric layer 162c2 may include different high-κ materials. The first and second lower high-κ dielectric layers 162b1 and 162b2 may each include an oxide containing a first metal element. The second upper high-κ dielectric layer 162c2 may include or be formed of an oxide containing a second metal element, different from the first metal element. The high-κ dielectric material is a dielectric material having a higher dielectric constant than silicon oxide (SiO₂), and may include or be formed of at least one of, for example, aluminum oxide (Al2O3), tantalum oxide (Ta2O3), titanium oxide (TiO2), yttrium oxide (Y2O3), zirconium oxide (ZrO2), zirconium silicon oxide (ZrSixOy), hafnium oxide (HfO2), hafnium silicon oxide (HfSixOy), lanthanum oxide (La2O3), lanthanum aluminum oxide (LaAlxOy), lanthanum hafnium oxide (LaHfxOy), hafnium aluminum oxide (HfAlxOy), and praseodymium oxide (Pr2O3).

The first composite dielectric layer 162m1 on the first lower high-κ dielectric layer 162b1 may include or be formed of the same oxide as the second composite dielectric layer 162m2 between the second lower high-κ dielectric layer 162b2 and the second upper high-κ dielectric layer 162c2. In an embodiment, the first and second composite dielectric layers 162m1 and 162m2 may each include a composite metal oxide containing both first and second metal elements.

In some embodiments, the first metal element includes or be formed of at least one of hafnium (Hf) and zirconium (Zr), and the first lower high-κ dielectric layer 162b1 and the second lower high-κ dielectric layer 162b2 may each include or be formed of hafnium oxide or zirconium oxide.

The second metal element is a metal element different from the first metal element, and may include or be formed of at least one of aluminum (Al), hafnium (Hf), zirconium (Zr), and lanthanum (La), and the second upper high-κ dielectric layer 162c2 may include or be formed of aluminum oxide, hafnium oxide, zirconium oxide, or lanthanum oxide.

For example, when the first and second lower high-κ dielectric layers 162b1 and 162b2 each includes hafnium oxide and the second upper high-κ dielectric layer 162c2 includes aluminum oxide, the first and second composite dielectric layers 162m1 and 162m2 may include or be formed of hafnium and aluminum-containing oxides, respectively.

The first lower high-κ dielectric layer 162b1 may have substantially the same thickness (t1b=t2b) as that of the second lower high-κ dielectric layer 162b2. For example, the thicknesses t1b and t2b of the first and second lower high-κ dielectric layers 162b1 and 162b2 may be in the range of 5 Å to 15 Å, respectively.

In the process of forming the gate insulating layer (see FIGS. 6C and 6D), the first composite dielectric layer 162m1 differs from the second composite dielectric layer 162m2 in the process of removing a first upper high-κ dielectric layer 162c1 located on the first composite dielectric layer 162m1. Some losses of the first composite dielectric layer 162m1 may occur. Accordingly, a thickness t1m of the first composite dielectric layer 162m1 may be substantially equal to or smaller than a thickness t2m of the second composite dielectric layer 162m2. For example, thicknesses t1m and t2m of the first and second composite dielectric layers 162m1 and 162m2 may be in the range of 2 Å to 10 Å, respectively. Meanwhile, a thickness t2c of the second upper high-κ dielectric layer 162c2 may be in the range of 5 Å to 15 Å.

Referring again to FIGS. 2A and 2B, the first and second gate insulating layers 162A and 162B may be disposed to extend in the second direction (e.g., the Y-direction) to the side surfaces of the first and second gate electrodes 165A and 165B. In some embodiments, the first and second gate insulating layers 162A and 162B may extend between the first and second gate electrodes 165A and 165B and the gate spacers 164.

The first and second gate electrodes 165A and 165B fill a gap between the first and second semiconductor channel layers 140A and 140B, above the first and second active patterns 105A and 105B, respectively, and may be formed above the uppermost channel layer. First and second gate insulating layers 162A and 162B may be disposed between the first and second gate electrodes 165A and 165B and the first and second semiconductor channel layers 140A and 140B, respectively.

The first and second gate electrodes 165A and 165B may include a conductive material. For example, each of the first and second gate electrodes 165A and 165B may include a metal nitride such as titanium nitride (TiN), tantalum nitride (TaN), or tungsten nitride (WN), and/or a metal material such as aluminum (Al), tungsten (W), or molybdenum (Mo) or a semiconductor material such as doped polysilicon. In some embodiments, at least one of the first and second gate electrodes 165A and 165B may include two or more multilayers. In some embodiments, the first and second gate electrodes 165A and 165B may mutually include conductive materials.

Gate spacers 164 may be disposed on both sides of each of the first and second gate electrodes 165A and 165B. The gate spacers 164 may insulate the first and second source/drain regions 150A and 150B and the first and second gate electrodes 165A and 165B. In some embodiments, the gate spacers 164 may have a multi-layered structure. For example, the gate spacers 164 may include oxide, nitride, and oxynitride, and may be particularly formed of a low dielectric constant layer. The gate capping layer 166 may be disposed on the first and second gate electrodes 165A and 165B, and lower and side surfaces of the gate capping layer 166 may be surrounded by the first and second gate electrodes 165A and 165B and the gate spacers 164, respectively.

Internal spacers 130 may be disposed in the first direction (e.g., the X-direction) on both side surfaces of the gate electrode portions disposed between the first and second semiconductor channel layers 140A and 140B in the vertical direction (e.g., the Z-direction). The first and second gate electrodes 165A and 165B may be spaced apart from and electrically separated from the first and second source/drain regions 150A and 150B by internal spacers 130, respectively. Side surfaces of the inner spacers 130 facing the first and second gate electrodes 165A and 165B may have convex curved surfaces, but are not limited thereto. For example, the inner spacers 130 may include oxide, nitride, and oxynitride. In particular, the inner spacers 130 may be formed of a low-κ film.

The first and second semiconductor channel layers 140A and 140B may have the same or similar widths as the first and second active patterns 105A and 105B in the second direction (Y-direction), respectively, and may have the same width as or a similar width to the width of the first and second gate structures 160A and 160B in the first direction (X-direction). The present inventive concept is not limited thereto, and in some embodiments, in each stack, the widths of the semiconductor channel layers 140A and 140B may be slightly different, but are not limited thereto.

A portion of the first active pattern 105A located on both sides of the first gate structures 160A may be recessed, and first source/drain regions 150A may be formed in the recessed area. Similarly, portions of the second active patterns 105B located on both sides of the second gate structures 160B are recessed, and second source/drain regions 150B may be formed in the recessed region. As illustrated in FIGS. 2A and 2B, the first and second source/drain regions 150A and 150B are respectively contact both sides of the first and second semiconductor channel layers 140A and 140B in the first direction (X-direction).

Each of the first and second source/drain regions 150A and 150B may include Si, SiGe, or Ge, and depending on the N-type or P-type transistor, each of the first and second source/drain regions 150A and 150B may have a different material or a different shape. For example, in the case of a PMOS transistor, the first and second source/drain regions 150A and 150B may include silicon-germanium (SiGe), and may be doped with a P-type impurity (e.g., boron (B), indium (In), or gallium (Ga)). Cross-sections (Y-Z cross-sections) of the first and second source/drain regions 150A and 150B may have a pentagonal shape. In contrast, in the case of an NMOS transistor, each of the first and second source/drain regions 150A and 150B may include silicon, and may be doped with N-type impurities (e.g., phosphorus (P), nitrogen (N), arsenic (As), antimony (Sb)). Cross-sections (Y-Z cross-sections) of the first and second source/drain regions 150A and 150B may be hexagonal or polygonal with gentle angles.

In this manner, the semiconductor device 100 according to the present embodiment includes a first transistor 100A including a first semiconductor channel layer 140A, first source/drain regions 150A, and a first gate structure 160A, and a second transistor 100B including a second semiconductor channel layer 140B, second source/drain regions 150B, and a second gate structure 160B, which may be respectively implemented as a gate-all-around type field effect transistor.

The first and second contacts 180A and 180B may pass through an interlayer insulating layer 190 and be connected to the first and second source/drain regions 150A and 150B. Electrical signals may be applied to the first and second source/drain regions 150A and 150B. As illustrated in FIG. 1, the first and second contacts 180A and 180B may be disposed on the first and second source/drain regions 150A and 150B. In some embodiments, the first and second contacts 180A and 180B may be disposed to have a longer length along the second direction (Y-direction) than the first and second source/drain regions 150A and 150B. The first and second contacts 180A and 180B may have inclined side surfaces where the width of the lower part is narrower than the width of the upper part according to the aspect ratio, but is not limited thereto. The first and second contacts 180A and 180B may extend below, for example, an uppermost semiconductor channel layer from the top. For example, the first and second contacts 180A and 180B may include a metal nitride such as titanium nitride (TiN), tantalum nitride (TaN), or tungsten nitride (WN), and/or may include a metal material such as aluminum (Al), tungsten (W), or molybdenum (Mo).

The interlayer insulating layer 190 may be formed to cover the first and second source/drain regions 150A and 150B, the first and second gate structures 160A and 160B, and the device isolation layer 110. For example, the interlayer insulating layer 190 may include at least one of oxide, nitride, and oxynitride, and may include a low-K material.

In an embodiment, the highly reliable first gate insulating layer 162A may be formed to a thin thickness that may be interposed between the first semiconductor channel layers 140A. In an embodiment, after stacking two high-κ dielectric layers (162b2 and 162c2) of different materials, a composite dielectric layer (162m2) may be formed between the high-κ dielectric layers through an annealing process. Therefore, the gate insulating layers 162A and 162B not only secure a high permittivity, but also greatly improve leakage current characteristics.

Furthermore, in the semiconductor device 100 according to the present embodiment, the first and second gate insulating layers 162A and 162B having different thicknesses and different dielectric properties may be formed using the same series of processes. This will be described in detail with reference to FIGS. 6A to 6E.

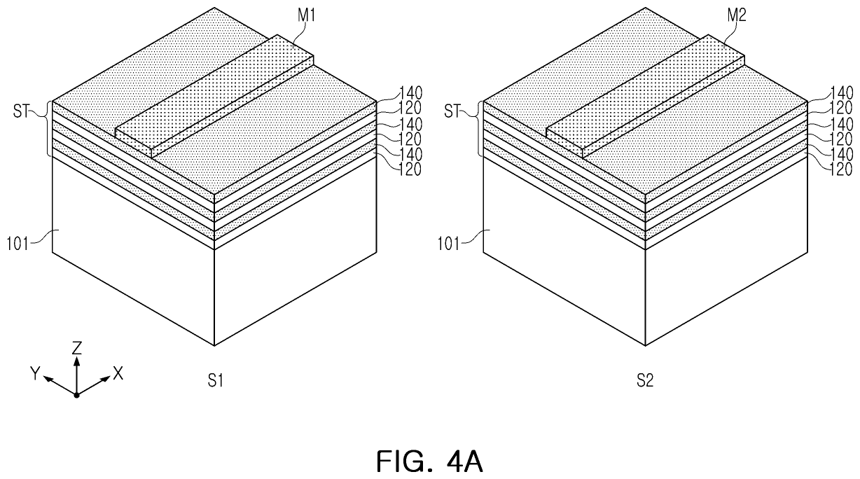

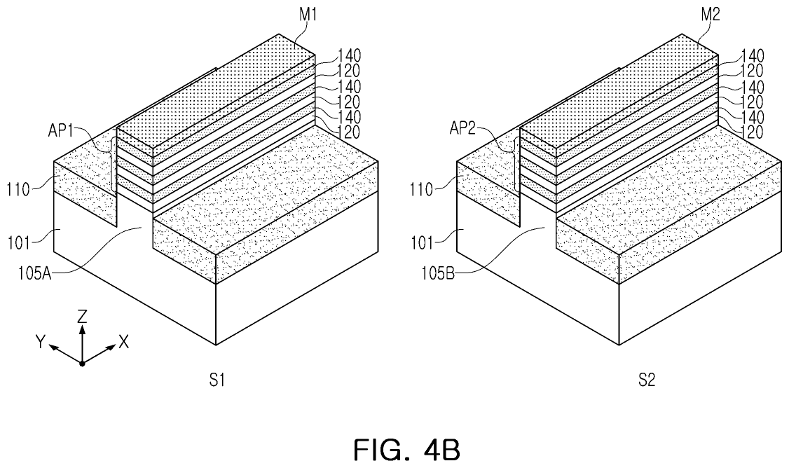

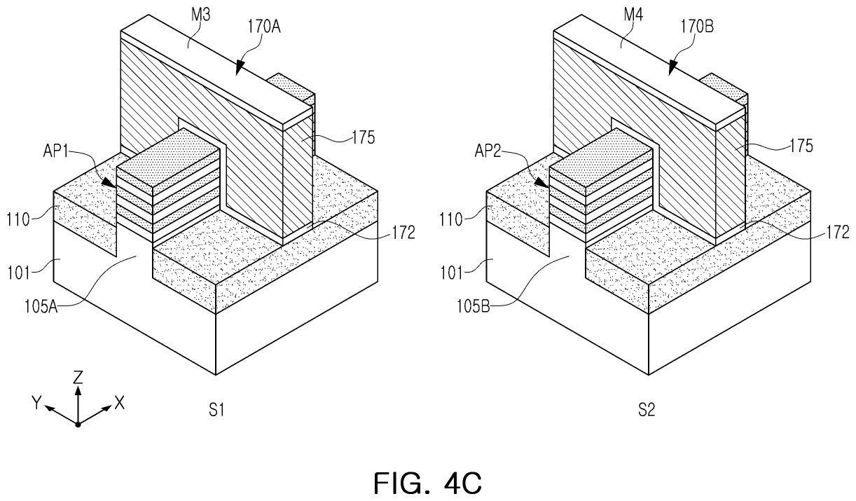

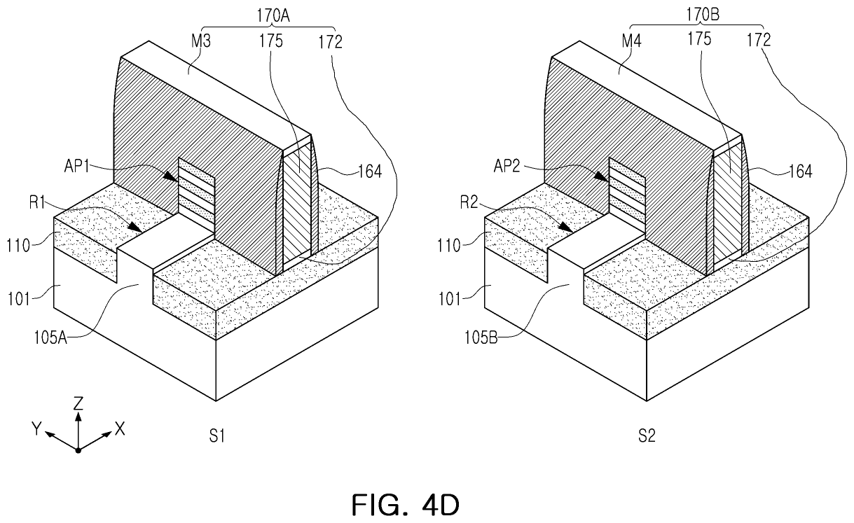

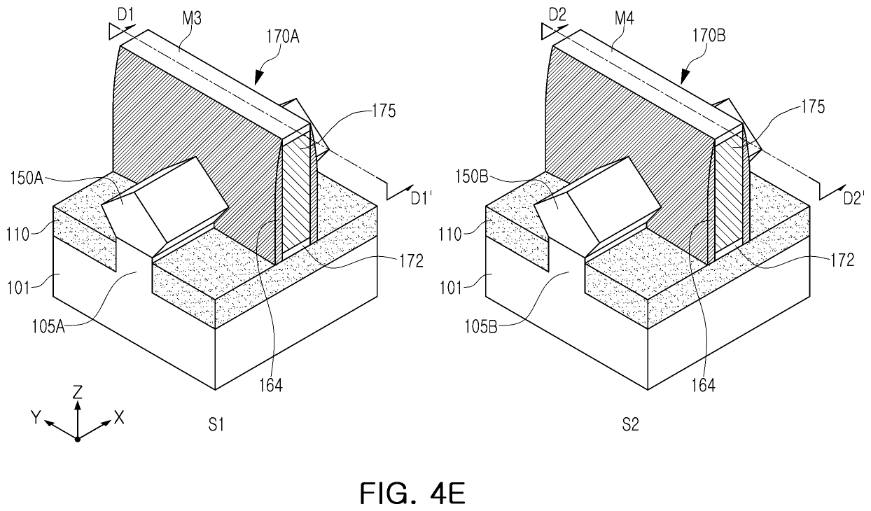

FIGS. 4A to 4E are perspective views illustrating some processes of a method of manufacturing a semiconductor device according to example embodiments.

Referring to FIG. 4A, on a substrate 101, sacrificial layers 120 and channel layers 140 may be alternately stacked to form a semiconductor stack ST.

The substrate 101 may include a first region Si and a second region S2. For example, the first region Si may be a logic cell or a logic circuit region, and the second region S2 may be a peripheral circuit region. Channel layers 140 and sacrificial layers 120 may be alternately stacked on the sacrificial layer 120 disposed on the substrate 101, and the uppermost layer of the semiconductor stack ST may be the channel layer 140. The sacrificial layers 120 and the channel layers 140 may each include semiconductor materials having different etch selectivities. For example, the sacrificial layers 120 provide a space for filling the gate electrode, and the channel layer 140 may be used as first and second semiconductor channel layers 140A and 140B, respectively. Even if the sacrificial layers 120 are etched, the channel layers 140 may remain almost unetched. The sacrificial layers 120 may include, for example, silicon germanium (SiGe) or germanium (Ge). The channel layers 140 may include, for example, silicon (Si).

Subsequently, first and second mask patterns M1 and M2 extending in the first direction X are formed on the semiconductor stack ST. For example, the first and second mask patterns M1 and M2 may be formed of at least one of a silicon oxide layer, a silicon nitride layer, and a silicon oxynitride layer.

Referring to FIG. 4B, the semiconductor stack ST may be etched using the first mask pattern M1 and the second mask pattern M2 as masks, respectively, thereby forming a first fin-type structure AP1 and a second fin-type structure AP2.

The first fin-type structure AP1 and the second fin-type structure AP2 may extend in the first direction (X-direction) on the first region Si and the second region S2, respectively. Each of the first and second fin-type structures AP1 and AP2 may include first semiconductor patterns and second semiconductor patterns alternately stacked on the first and second regions of the substrate 101, respectively.

In example embodiments, active patterns 105A and 105B protruding under the first fin-type structure API and the second fin-type structure AP2 may be formed by further etching a partial region of the substrate 101. A device isolation layer 110 may be formed around the active patterns 105A and 105B. The device isolation layer 110 may partially cover side surfaces of the active patterns 105A and 105B. A top surface of the device isolation layer 110 may be formed lower than a top surface of the active patterns 105A and 105B on the substrate 101. That is, the active patterns 105A and 105B on the substrate 101 may protrude above the device isolation layer 110.

Subsequently, a dummy gate structure and source/drain formation process may be performed (see FIGS. 4C to 4E).

Referring to FIG. 4C, first and second sacrificial gate structures 170A and 170B extending in a second direction (Y-direction) across the first and second fin-type structures API and AP2 are formed, respectively.

A buffer layer 172 and a sacrificial gate material layer 175 are formed on the first region S1 and the second region S2 to cover the first fin-type structure API and the second fin-type structure AP2, and third and fourth mask patterns M3 and M4 extending in the second direction (Y-direction) are formed. For example, the first sacrificial gate structure 170A may include the third mask pattern M3, the buffer layer 172, and the sacrificial gate material layer 175. The second sacrificial gate structure 170B may include the fourth mask pattern M4, the buffer layer 172, and the sacrificial gate material layer 175. The first and second sacrificial gate structures 170A and 170B may be formed by performing an etching process using the third and fourth mask patterns M3 and M4. For example, the buffer layer 172 may include silicon oxide or silicon oxynitride, and the sacrificial gate material layer 175 may include polysilicon or amorphous silicon.

Subsequently, referring to FIG. 4D, gate spacers 164 may be formed on both sidewalls of each of the first and second sacrificial gate structures 170A and 170B, and exposed regions of the first and second fin-type structures AP1 and AP2 outside the gate spacers 164 are removed to form first and second recess regions.

First, a spacer material layer is formed on the substrate 101 to cover the first and second sacrificial gate structures 170A and 170B and the first and second fin-type structures AP1 and AP2. The remaining gate spacers 164 may be formed on both sidewalls of the first and second sacrificial gate structures 170A and 170B by etching back the spacer material layer. The gate spacers 164 may include, for example, at least one of silicon nitride (SiN), silicon oxynitride (SiON), silicon oxide (SiO2), silicon oxycarbonitride (SiOCN), and combinations thereof. In an embodiment, each of the gate spacers 164 is illustrated as a single layer, but is not limited thereto and may have a multilayer structure.

After forming the gate spacers 164, a region of the first fin-type structure AP1 exposed from the outside of the gate spacers 164 is removed to form a first recess R1 on both sides of the first fin-type structure AP1, and similarly, the regions of the second fin-type structure AP2 exposed from the outside of the gate spacers 164 are removed to form the second recess R2 on both sides of the second fin-type structure AP2. The process of forming the first recess R1 and the process of forming the second recess R2 may be performed simultaneously. In some embodiments, after this process, removing some regions from both sides of the sacrificial layers 120 between the channel layers 140, a process for forming an internal spacer (see “130” in FIGS. 2A and 2B) may be additionally performed in the removed space.

Next, referring to FIG. 4E, epitaxial growth may be performed on the first recess R1 of the first fin-type structure AP1 and the second recess R2 of the second fin-type structure AP2.

Epitaxial growth in the first recesses R1 on both sides of the first sacrificial gate structure 170A may serve as first source/drain regions 150A. Epitaxial growth in the second recesses R2 on both sides of the second sacrificial gate structure 170B may serve as second source/drain regions 150B. In this epitaxial growth process, the semiconductor surfaces of the first and second active patterns 105A and 105B exposed on the bottom surfaces of the first and second recesses R1 and R2 and both side regions of the first and second semiconductor channel layers 140A and 140B exposed on the side surfaces of the first and second recesses R1 and R2 may be used as the seed layers.

Each of the first and second source/drain regions 150A and 150B may include Si, SiGe, or Ge, and depending on the N-type or P-type transistor, the source/drain regions 150A and 150B may have other materials or other shapes. For example, in the case of a PMOS transistor, each of the first and second source/drain regions 150A and 150B may include silicon-germanium (SiGe), and may be doped with a P-type impurity (e.g., boron (B), indium (In), or gallium (Ga)). Cross-sections (Y-Z cross-sections) of the first and second source/drain regions 150A and 150B may have a pentagonal shape. In contrast, in the case of an NMOS transistor, each of the first and second source/drain regions 150A and 150B may include silicon, and may be doped with N-type impurities (e.g., phosphorus (P), nitrogen (N), arsenic (As), antimony (Sb)). Cross-sections (Y-Z cross-sections) of the first and second source/drain regions 150A and 150B may be hexagonal or polygonal with gentle angles.

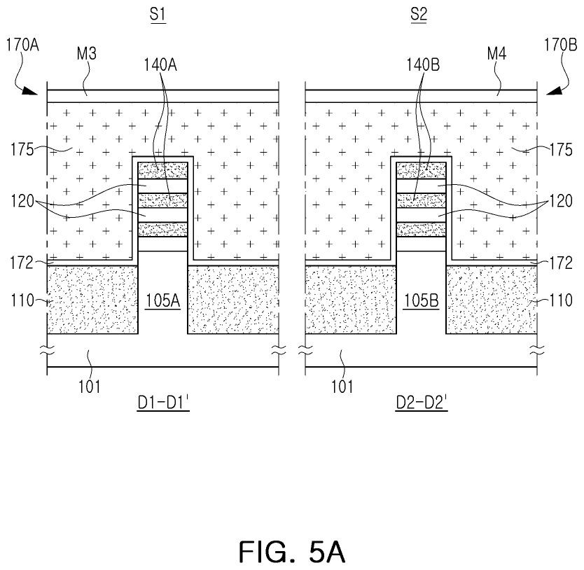

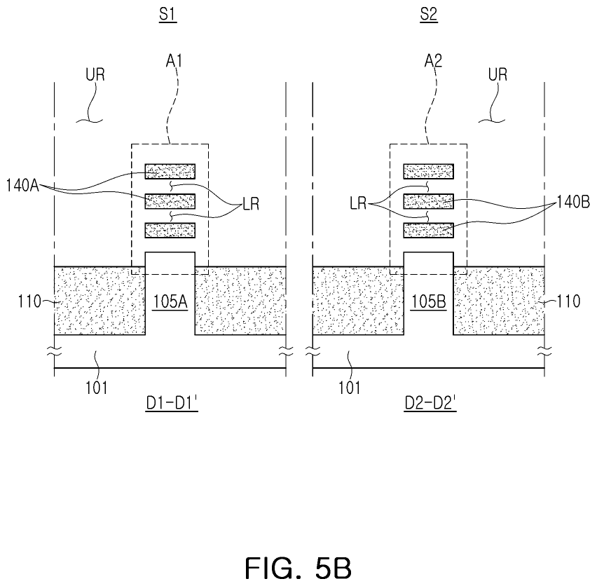

FIGS. 5A and 5B are cross-sectional views illustrating some processes (a process of removing a dummy gate structure) of a method of manufacturing a semiconductor device according to an exemplary embodiment. In this case, FIG. 5A is a cross-sectional view of the first and second semiconductor structures of FIG. 4E cut at D1-D1′ and D2-D2′, respectively.

An interlayer insulating layer 190 may be formed on the first and second semiconductor structures illustrated in FIG. 5A, to cover the first and second source/drain regions 150A and 150B and the first and second sacrificial gate structures 170A and 170B, and may then be formed by performing a planarization process. During the planarization process, the sacrificial gate material layer 175 may be exposed between the gate spacers 164.

Subsequently, as illustrated in FIG. 5B, the first and second sacrificial gate structures 170A and 170B are removed from the first and second semiconductor structures, respectively, to form upper gap regions UR and lower gap regions (LR).

In detail, the upper gap regions UR are formed by removing the sacrificial gate material layer 175, and subsequently, the lower gap regions LR may be formed by removing the sacrificial layers 120 exposed through the upper gap regions UR. For example, when the sacrificial layers 120 include silicon germanium (SiGe) and the first and second semiconductor channel layers 140A and 140B include silicon (Si), the sacrificial layers 120 may be selectively removed by performing a wet etching process using peracetic acid as an etchant. During the removal process, the first and second source/drain regions 150A and 150B may be protected by an interlayer insulating layer 190 and internal spacers 130.

FIGS. 6A to 6E are cross-sectional views illustrating some processes (a gate insulating layer forming process) of a method of manufacturing a semiconductor device according to an exemplary embodiment. The cross-sectional views of FIGS. 6A to 6E correspond to enlarged views illustrating the portion A1 of FIG. 2A and the portion A2 of FIG. 2B, respectively. In the manufacturing process according to the present embodiment, the first and second gate insulating layers 162A and 162B may be formed together through the same series of processes.

Referring to FIG. 6A, first and second interfacial insulating layers 162a1 and 162a2 may be formed on surfaces of the first and second semiconductor channel layers 140A and 140B, respectively, and subsequently, first and second lower high-κ dielectric layers 162b1′ and 162b2′ are sequentially formed on the first and second interfacial insulating layers 162a1 and 162a2, respectively.

The first and second interfacial insulating 150A and 150B 162a1 and 162a2 and the first and second lower high-κ dielectric films 162b1′ and 162b2′ may be formed to surround the first and second semiconductor channel layers 140A and 140B in a second direction (e.g., Y-direction), respectively, and additionally, may be disposed on the protruding surfaces of the first and second active patterns 105A and 105B, and may extend on the upper surface of the device isolation layer 110 in a second direction (e.g., Y-direction).

The first and second interfacial insulating layers 162a1 and 162a2 may be formed through the same process. For example, the first and second interfacial insulating layers 162a1 and 162a2 may be formed simultaneously. The first and second lower high-κ dielectric layers 162b1′ and 162b2′ may be formed through the same process. For example, the first and second lower high-κ dielectric layers 162b1′ and 162b2′ may be formed simultaneously.

The first interfacial insulating layer 162a1 may include the same dielectric material as the second interfacial insulating layer 162a2. For example, each of the first and second interfacial insulating layers 162a1 and 162a2 may include or be formed of silicon oxide or silicon oxynitride. The first and second interfacial insulating layers 162a1 and 162a2 may have substantially the same thickness (t1a=t2a). For example, the thicknesses t1a and t2a of the first and second interfacial insulating layers 162a1 and 162a2 may be in the range of 5 Å to 10 Å, respectively.

The first and second lower high-κ dielectric layers 162b1′ and 162b2′ may each include the same high-κ material containing the first metal element. Each of the first and second lower high-κ dielectric layers 162b1′ and 162b2′ may include or be formed of at least one of, for example, aluminum oxide (Al2O3), tantalum oxide (Ta2O3), titanium oxide (TiO2), yttrium oxide (Y2O3), zirconium oxide (ZrO2), zirconium silicon oxide (ZrSixOy), hafnium oxide (HfO2), hafnium silicon oxide (HfSixOy), lanthanum oxide (La2O3), lanthanum aluminum oxide (LaAlxOy), lanthanum hafnium oxide (LaHfxOy), hafnium aluminum oxide (HfAlxOy), and praseodymium oxide (Pr2O3).

In some embodiments, the first metal element may include or be formed of at least one of hafnium (Hf) and zirconium (Zr), and the first and second lower high-κ dielectric layers 162b1′ and 162b2′ may each include or be formed of hafnium oxide or zirconium oxide.

In example embodiments, the first lower high-κ dielectric layer 162b1′ may have substantially the same thickness (t1b′=t2b′) as that of the second lower high-κ dielectric layer 162b2′. In the subsequent heat treatment process, since some upper regions of the first and second lower high-κ dielectric films 162b1′ and 162b2′ may be converted into composite dielectric films, respectively, the final thickness (t1b and t2b) thereof may be reduced from the deposited thickness (t1b′ and t2b′) in this heat treatment process.

Next, referring to FIG. 6B, first and second upper high-κ dielectric layers 162c1′ and 162c2′ are formed on the first and second lower high-κ dielectric layers 162b1′ and 162b2′, respectively.

The first and second upper high-κ dielectric layers 162c1′ and 162c2′ may be formed through the same process. For example, the first and second upper high-κ dielectric layers 162c1′ and 162c2′ may be formed simultaneously. The first and second upper high-κ dielectric layers 162c1′ and 162c2′ may each include the same high-κ material containing a second metal element different from the first metal element. Each high-κ material of the first and second upper high-κ dielectric layers 162c1′ and 162c2′ is a dielectric material different from each high-κ material of the first and second lower high-κ dielectric films 162b1′ and 162b2′, and may include or be formed of at least one of aluminum oxide (Al2O3), tantalum oxide (Ta2O3), titanium oxide (TiO2), yttrium oxide (Y2O3), zirconium oxide (ZrO2), zirconium silicon oxide (ZrSixOy), hafnium oxide (HfO2), hafnium silicon oxide (HfSixOy), Lanthanum oxide (La2O3), lanthanum aluminum oxide (LaAlxOy), lanthanum hafnium oxide (LaHfxOy), hafnium aluminum oxide (HfAlxOy), and praseodymium oxide (Pr2O3).

In some embodiments, the second metal element is a metal element different from the first metal element, and may include or be formed of at least one of aluminum (Al), hafnium (Hf), zirconium (Zr), and lanthanum (La), and each of the first and second upper high-κ dielectric layers 162c1′ and 162c2′ may include or be formed of aluminum oxide, hafnium oxide, zirconium oxide, or lanthanum oxide.

In example embodiments, the first upper high-κ dielectric layer 162c1′ may have substantially the same thickness (t1c′=t2c′) as that of the second upper high-κ dielectric layer 162c2′. In the subsequent heat treatment process, some lower regions of the first and second upper high-κ dielectric layers 162c1′ and 162c2′ may be converted into composite dielectric layers, respectively, and the final thickness (tic and t2c) thereof may be slightly reduced from the deposited thickness (tic′ and t2c′) in this heat treatment process.

Next, referring to FIG. 6C, a metal nitride layer 210 and a polysilicon capping layer 220 may be formed on the first and second upper high-κ dielectric layers 162c1′ and 162c2′. The metal nitride layer 210 may be conformally formed as a barrier layer similar to previously formed dielectric layers. For example, the metal nitride layer 210 may include TiN. Then, the polysilicon capping layer 220 may be formed to surround each of the first semiconductor channel layers 140A and the second semiconductor channel layers 140B while filling the spaces between the first semiconductor channel layers 140A and the spaces between the second semiconductor channel layers 140B.

Next, referring to FIG. 6D, an annealing process is applied to stacks of high-κ dielectric layers formed on each of the first semiconductor channel layers 140A and the second semiconductor channel layers 140B. The annealing process may be performed in a temperature range of 900° C. to 1050° C. After the annealing process, a first composite dielectric layer 162m1 may be formed between the first lower high-κ dielectric layer 162b1 and a first upper high-κ dielectric layer 162c1, and similarly, a second composite dielectric layer 162m2 may be formed between a second lower high-κ dielectric layer 162b2 and a second upper high-κ dielectric layer 162c2. The first and second composite dielectric layers 162m1 and 162m2 may be formed through the same process. For example, the first and second composite dielectric layers 162m1 and 162m2 may be formed simultaneously.

Each of the first composite dielectric layer 162m1 and the second composite dielectric layer 162m2 may include or be formed of substantially the same oxide. In an embodiment, each of the first and second composite dielectric layers 162m1 and 162m2 may include or be formed of a composite metal oxide containing both first and second metal elements.

For example, when each of the first and second lower high-κ dielectric layers 162b1 and 162b2 includes hafnium oxide, and each of the first and second upper high-κ dielectric layers 162c1 and 162c2 includes aluminum oxide, the first and second composite dielectric layers 162m1 and 162m2 may each include or be formed of an oxide containing hafnium and aluminum.

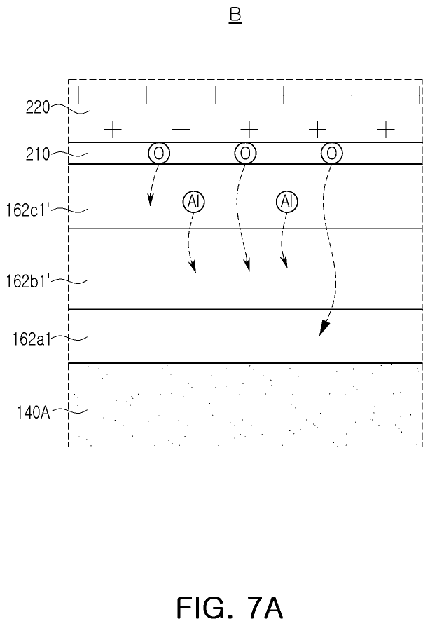

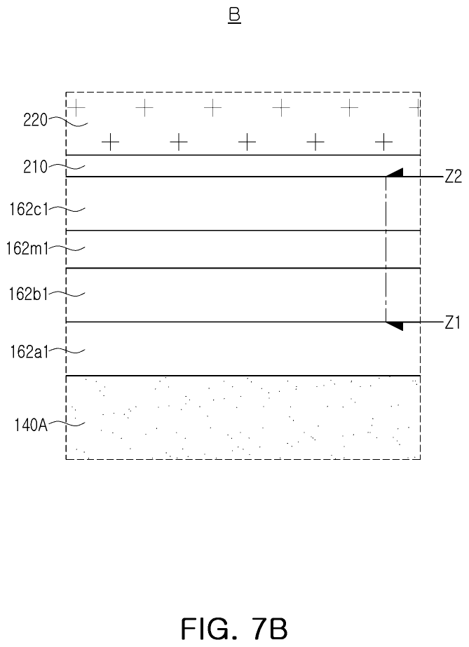

FIGS. 7A and 7B are partially enlarged views illustrating regions “B” of FIGS. 6C and 6D to describe the annealing process.

As illustrated in FIG. 7A, in the first transistor 100A disposed on the first region S1, oxygen is diffused into the first upper high-κ dielectric layer 162c1′ and the first lower high-κ dielectric layer 162b1′ when the annealing process is started. Oxygen vacancy curing of the first upper high-κ dielectric layer 162c1′, the first lower high-κ dielectric layer 162b1′, and the first interfacial insulating layer 162a1 may be performed. In addition, in this annealing process, the second metal element (e.g., Al) of the first upper high-κ dielectric layer 162c1′ may be diffused into the first lower high-κ dielectric layer 162b1′. Similarly, in the second transistor 100B disposed on the second region S2, oxygen is diffused into the second upper high-κ dielectric layer 162c2′ and the second lower high-κ dielectric layer 162b2′ when the annealing process is started. Oxygen vacancy curing of the second upper high-κ dielectric layer 162c2′, the second lower high-κ dielectric layer 162b2′, and the second interfacial insulating layer 162a2 may be performed. In addition, in this annealing process, the second metal element (e.g., Al) of the second upper high-κ dielectric layer 162c2′ may be diffused into the second lower high-κ dielectric layer 162b2′.

As illustrated in FIG. 7B, in the first transistor 100A disposed on the first region Si, when the annealing process is performed the first composite dielectric layer 162m1 containing a first metal element (e.g., Hf) and a second metal element (e.g., Al) may be formed in an upper region of the first lower high-κ dielectric layer 162b1. In some embodiments, the first metal element (e.g., Hf) of the first lower high-κ dielectric layer 162b1 may also be additionally diffused into the first upper high-κ dielectric layers 162c1, and the first composite dielectric layer 162m1 may be formed on the upper region of the first lower high-κ dielectric layer 162b1 and the lower region of the first upper high-κ dielectric layer 162c1. Similarly, in the second transistor 100B disposed on the second region S2, when the annealing process is performed the second composite dielectric layers 162m2 containing the first metal element (e.g., Hf) and the second metal element (e.g., Al) may be formed in the upper region of the second lower high-κ dielectric layer 162b2. In some embodiments, the first metal element (e.g., Hf) of the second lower high-κ dielectric layer 162b2 may also be additionally diffused into the second upper high-κ dielectric layer 162c2, and the second composite dielectric layer 162m2 may be formed on the upper region of the second lower high-κ dielectric layer 162b2 and the lower region of the second upper high-κ dielectric layer 162c2.

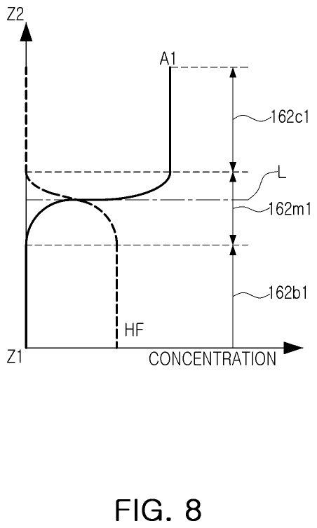

For example, as illustrated in FIGS. 6D and 8, in the first transistor 100A disposed on the first region Si, the first composite dielectric layer 162m1 may be formed in an upper region of the first lower high-κ dielectric layer 162b1 and a lower region of the first upper high-κ dielectric layer 162c1, based on the interface L between the first lower high-κ dielectric layer 162b1 and the first upper high-κ dielectric layer 162c1. Also, the first composite dielectric layer 162m1 may have concentration distributions inclined (e.g., exponentially) by diffusion of the first and second metal elements. Similarly, in the second transistor 100B disposed on the second region S2, the second composite dielectric layer 162m2 may be formed in an upper region of the second lower high-κ dielectric layer 162b2 and a lower region of the second upper high-κ dielectric layer 162c2, based on the interface L between the second lower high-κ dielectric layer 162b2 and the second upper high-κ dielectric layer 162c2. Also, the second composite dielectric layer 162m2 may have concentration distributions inclined (e.g., exponentially) by diffusion of the first and second metal elements.

In example embodiments, the first and second composite dielectric layers 162m1 and 162m2 may have substantially the same thickness (t1m=t2m). For example, the thicknesses t1m and t2m″ of the first and second composite dielectric layers 162m1 and 162m2 may respectively range from 2 Å to 10 Å.

Thicknesses t1b and t2b of the first and second lower high-κ dielectric layers 162b1 and 162b2 may be substantially the same, and thicknesses t1c and t2c of the first and second upper high-κ dielectric layers 162c1 and 162c2 may also be substantially the same. For example, the thicknesses t1b and t2b of the first and second lower high-κ dielectric layers 162b1 and 162b2 may range from 5 Å to 15 Å. Similarly, the thicknesses t1c and t2c of the first and second upper high-κ dielectric layers 162c1 and 162c2 may also range from 5 Å to 15 Å.

Next, referring to FIG. 6E, the metal nitride layer 210 and the polysilicon capping layer 220 used in the annealing process are removed from both the first and second regions S1 and S2, and additionally, the first upper high-κ dielectric layer 162c1 on the first composite dielectric layer 162m1 in the first region Si may be removed.

Through the selective removal process of the first upper high-κ dielectric layer 162c1, the first gate insulating layer 162A may form a thin gate insulating layer unlike the thick second gate insulating layer 162B. In detail, the second gate insulating layer 162B may include a second interface insulating layer 162a2, a second lower high-κ dielectric layer 162b2, a second composite dielectric layer 162m2, and a second upper high-κ dielectric layer 162c2, and the first gate insulating layer 162A includes a first interfacial insulating layer 162a1, a first lower high-κ dielectric layer 162b1, and a first composite dielectric layer 162m1 formed by the same process as each dielectric layer of the second gate insulating layer 162B.

Unlike the second composite dielectric layer 162m2, the first composite dielectric layer 162m1 may experience some loss during the process of removing the first upper high-κ dielectric layer 162c1 located thereon. For example, the thickness t1m of the first composite dielectric layer 162m1 may be substantially equal to or smaller than the thickness t2m of the second composite dielectric layer 162m2.

As such, the first gate insulating layer 162A of the first transistor 100A has a relatively thin first thickness T1, and the second gate insulating layer 162B of the second transistor 100B may have a second thickness T2 greater than the first thickness Ti. Although the second thickness T2 of the second gate insulating layer 162B is formed with a thickness smaller than at least ½ times the second distance G2 such that a space in which the second gate electrode 165B may be interposed may remain between the second semiconductor channel layers 140A, the second thickness T2 of the second gate insulating layer 162B may be provided as a high-κ dielectric film suitable for high voltage resistance. In some embodiments, the second thickness T2 may be 50 Å or less, for example, 40 Å or less.

The first gate insulating layer (e.g., SiO₂/HfO₂/(Al,Hf)Oₓ) according to the present embodiment has almost the same Equivalent Oxide Thickness (EOT) as other gate insulating layers (SiO₂/HfO₂) not including the first composite high-κ dielectric layer, and may be reduced to 30% or less, and leakage current may be reduced. In addition, the second gate insulating layer (e.g., SiO₂/HfO₂/(Al,Hf)Oₓ/Al₂O₃) according to the present embodiment has an EOT 1.5 times that of other gate insulating layers not including the second composite high-κ dielectric layer, and leakage current may be greatly reduced to 0.01% or less.

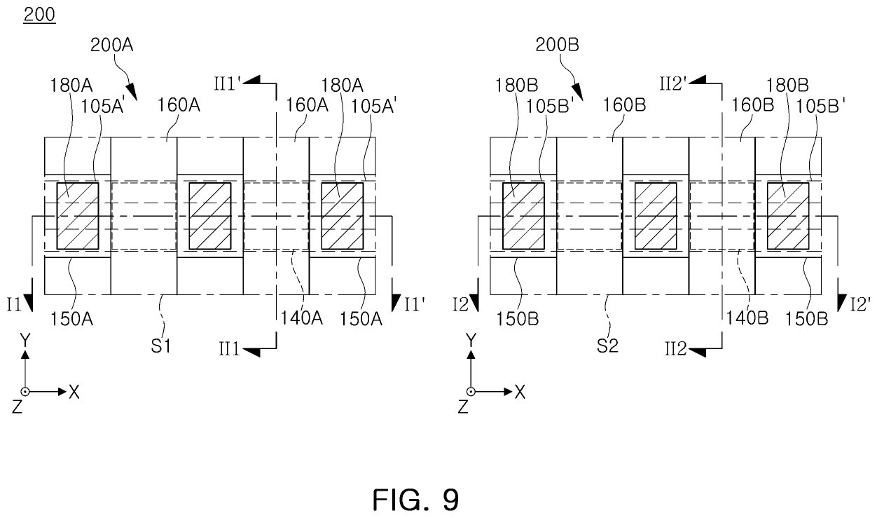

FIG. 9 is a plan view illustrating a semiconductor device according to an exemplary embodiment, and FIG. 10A is cross-sectional views of a first region of the semiconductor device illustrated in FIG. 9 taken along lines I1-I1′ and II1-II1′. FIG. 10B is cross-sectional views of the second region of the semiconductor device illustrated in FIG. 9 taken along lines I2-I2′ and II2-II2′.

Referring to FIGS. 9, 10A, and 10B, it may be understood that a semiconductor device 200 according to the present embodiment is similar to the semiconductor device 100 illustrated in FIGS. 1, 2A, 2B, 3A, and 3B except that the fin-type structures AP1 and AP2 are provided as the active fins 105A′ and 105B′. In addition, elements of the present embodiment may be understood with reference to descriptions of the same or similar elements of the semiconductor device 100 illustrated in FIGS. 1, 2A, 2B, 3A, and 3B unless otherwise stated. The semiconductor device 200 may include a first transistor 200A disposed on a first region S1 of a substrate 101, and a second transistor 200B disposed on a second region S2 of the substrate 101.

In example embodiments, the semiconductor device 200 may include at least one of first and second active fins 105A′ and 105B′ in the first and second regions S1 and S2, respectively. The first and second active fins 105A′ and 105B′ each have a structure protruding from the upper surface of the substrate 101 upward (e.g., Z-direction) and extend in a first direction (e.g., X-direction). As illustrated in FIGS. 10A and 10B, first and second active fins 105A′ and 105B′ may be arranged side by side in the second direction (e.g., Y-direction) on the substrate 101. In an embodiment, two active fins arranged adjacently provide a channel region for one transistor. In an embodiment, each of the first and second active fins 105A′ and 1053 is exemplified as being provided by two, respectively, but is not limited thereto, and may be provided singly or in other plural numbers.

Referring to FIGS. 9 and 10A and 10B, the semiconductor device 200 according to the present embodiment may respectively include first and second source/drain regions 150A and 150B formed across two active fins 105A′ and 1053 in the first and second regions S1 and S2, and first and second contacts 180A and 180B connected to the first and second source/drain regions 150A and 150B, respectively.

The semiconductor device 200 according to this embodiment may include a plurality of first and second gate structures 160A and 160B in the first and second regions S1 and S2, respectively. The first and second gate structures 160A and 160B may each extend in the second direction (e.g., the Y-direction). The first and second gate structures 160A and 160B may overlap one region of each of the first and second active fins 105A′ and 105B′, respectively. The first gate structure 160A may include gate spacers 164, a first gate insulating layer 162A and a first gate electrode 165A sequentially disposed between the gate spacers 164, and a gate capping layer 166 disposed on the first gate electrode 165A. Similarly, the second gate structures 160B may respectively include gate spacers 164, a second gate insulating layer 162B and a second gate electrode 165B sequentially disposed between the gate spacers 164, and a gate capping layer 166 disposed on the second gate electrode 165B. For example, each of the first and second transistors 200A and 200B may be FinFET device in which each of the first and second active fins 105A′ and 105B′ has a fin structure.

Similar to the previous embodiment, the first gate insulating layer 162A employed in this embodiment may include a first interfacial insulating layer 162a1, a first lower high-κ dielectric layer 162b1, and a first composite dielectric layer 162m1 sequentially stacked on the surfaces of the first active fins 105A′. Similarly, the second gate insulating layer 162B may include a second interfacial insulating layer 162a2, a second lower high-κ dielectric layer 162b2, a second composite dielectric layer 162m2, and a second upper high-κ dielectric layer 162c2 sequentially stacked on the surface of each of the second active fins 105B′.

The first interfacial insulating layer 162a1 may include the same dielectric material as the second interfacial insulating layer 162a2. For example, each of the first and second interfacial insulating layers 162a1 and 162a2 may include or be formed of silicon oxide or silicon oxynitride. The first and second interfacial insulating layers 162a1 and 162a2 may have substantially the same thickness (t1a=t2a).

The first and second lower high-κ dielectric layers 162b1 and 162b2 and the second upper high-κ dielectric layer 162c2 may include or be formed of different high-κ materials. The first and second lower high-κ dielectric layers 162b1 and 162b2 may each include or be formed of an oxide containing a first metal element. The second upper high-κ dielectric layer 162c2 may include or be formed of an oxide containing a second metal element, different from the first metal element. The first composite dielectric layer 162m1 on the first lower high-κ dielectric layer 162b1 may include or be formed of the same oxide as the second composite dielectric layer 162m2 between the second lower high-κ dielectric layer 162b2 and the second upper high-κ dielectric layer 162c2. In an embodiment, the first and second composite dielectric layers 162m1 and 162m2 may each include or be formed of a composite metal oxide containing both first and second metal elements.

In some embodiments, the first metal element may include at least one of hafnium (Hf) and zirconium (Zr), and the first lower high-κ dielectric layer 162b1 and the second lower high-κ dielectric layer 162b2 may each include or be formed of hafnium oxide or zirconium oxide.

The second metal element may be a metal element different from the first metal element, and may include or be formed of at least one of aluminum (Al), hafnium (Hf), zirconium (Zr), and lanthanum (La), and the second upper high-κ dielectric layer 162c2 may include or be formed of aluminum oxide, hafnium oxide, zirconium oxide, or lanthanum oxide.

For example, when the first and second lower high-κ dielectric layers 162b1 and 162b2 each includes hafnium oxide, and the second upper high-κ dielectric layer 162c2 includes aluminum oxide, the first and second composite dielectric layers 162m1 and 162m2 may each include or be formed of an oxide containing hafnium and aluminum.

In some embodiments, the first and second interfacial insulating layers 162a1 and 162a2 may have substantially the same thickness (t1a=t2a). For example, the thicknesses t1a and t2a of the first and second interfacial insulating layers 162a1 and 162a2 may be in the range of 5 Å to 10 Å, respectively. The first lower high-κ dielectric layer 162b1 may have substantially the same thickness (t1b=t2b) as that of the second lower high-κ dielectric layer 162b2. For example, the thicknesses t1b and t2b of the first and second lower high-κ dielectric layers 162b1 and 162b2 may be in the range of 5 Å to 15 Å, respectively. A thickness t1m of the first composite dielectric layer 162m1 may be substantially equal to or smaller than a thickness t2m of the second composite dielectric layer 162m2. Meanwhile, a thickness t2c of the second upper high-κ dielectric layer 162c2 may be in the range of 5 Å to 15 Å.

As described above, the first transistor 200A is a device for fast operation and may have the thin first gate insulating layer 162A having excellent reliability (e.g., leakage current reduction), and the second transistor 200B is a device having high voltage resistance and may have the thick second gate insulating layer 162B having excellent reliability (e.g., reduction of leakage current).

As set forth above, according to example embodiments, a method of forming a highly reliable gate insulating layer with improved leakage current characteristics to a thin thickness that may be interposed between semiconductor channel layers is provided. According to this formation method, a relatively thin first gate insulating layer of the first transistor and a relatively thick second gate insulating layer of the second transistor may be simultaneously formed on the same substrate.

While example embodiments have been illustrated and described above, it will be apparent to those skilled in the art that modifications and variations could be made without departing from the scope of the present inventive concept as defined by the appended claims.

1. A semiconductor device comprising:
a first transistor on a first region of a substrate; and
a second transistor on a second region of the substrate,
wherein the first transistor includes:
first semiconductor channel layers spaced apart from each other and stacked on the first region of the substrate in a vertical direction perpendicular to an upper surface of the substrate,
a first gate insulating layer surrounding the first semiconductor channel layers, and including a first interfacial insulating layer, a first lower high-κ dielectric layer containing a first metal element, and a first composite dielectric layer containing the first metal element and a second metal element different from the first metal element, the first interfacial insulating layer, the first lower high-κ dielectric layer and the first composite dielectric layer sequentially stacked on each of the first semiconductor channel layers, and
a first gate electrode on the first gate insulating layer, and
wherein the second transistor includes:
second semiconductor channel layers spaced apart from each other and stacked on a second region of the substrate in the vertical direction,
a second gate insulating layer surrounding the second semiconductor channel layers, and including a second interfacial insulating layer, a second lower high-κ dielectric layer containing the first metal element, a second composite dielectric layer containing the first metal element and the second metal element, and a second upper high-κ dielectric layer containing the second metal element, the second interfacial insulating layer, the second lower high-κ dielectric layer, the second composite dielectric layer, and the second upper high-κ dielectric layer sequentially stacked on each of the second semiconductor channel layers, and
a second gate electrode on the second gate insulating layer.

2. The semiconductor device of claim 1, wherein the second gate insulating layer has a thickness greater than that of the first gate insulating layer.

3. The semiconductor device of claim 2, wherein the thickness of the second gate insulating layer is 40 Å or less.

4. The semiconductor device of claim 1, wherein the first metal element includes at least one of hafnium (Hf) and zirconium (Zr), and
wherein each of the first lower high-κ dielectric layer and the second lower high-κ dielectric layer includes hafnium oxide or zirconium oxide.

5. The semiconductor device of claim 1, wherein the first lower high-κ dielectric layer and the second lower high-κ dielectric layer have the same thickness.

6. The semiconductor device of claim 5, wherein the thickness of each of the first and second lower high-κ dielectric layers is in a range of 5 Å to 15 Å.

7. The semiconductor device of claim 1, wherein the second metal element includes at least one of aluminum (Al), hafnium (Hf), zirconium (Zr), and lanthanum (La), and
wherein the second upper high-κ dielectric layer includes aluminum oxide, hafnium oxide, zirconium oxide, or lanthanum oxide.

8. The semiconductor device of claim 1, wherein each of the first composite dielectric layer and the second composite dielectric layer includes the same oxide containing the first metal element and the second metal element.

9. The semiconductor device of claim 8, wherein the first metal element includes at least one of hafnium and zirconium, and
wherein the second metal element includes at least one of aluminum, hafnium, zirconium, and lanthanum.

10. The semiconductor device of claim 1, wherein each of the first and second composite dielectric layers has a thickness in a range of 2 Å to 10 Å, and
wherein the thickness of the second upper high-κ dielectric layer is in a range of 5 Å to 15 Å.

11. The semiconductor device of claim 1, wherein each of the first and second lower high-κ dielectric layers includes hafnium oxide,
wherein the second upper high-κ dielectric layer includes aluminum oxide, and
wherein each of the first and second composite dielectric layers includes an oxide containing hafnium and aluminum.

12. The semiconductor device of claim 1, wherein each of the first interfacial insulating layer and the second interfacial insulating layer includes the same dielectric material.

13. The semiconductor device of claim 12, wherein each of the first and second interfacial insulating layers includes silicon oxide or silicon oxynitride.

14. The semiconductor device of claim 12, wherein each of the first interfacial insulating layer and the second interfacial insulating layer has the same thickness.

15. The semiconductor device of claim 14, wherein the thickness of each of the first and second interfacial insulating layers is in a range of 5 Å to 10 Å.

16. A semiconductor device comprising:
a substrate including an active pattern extending in a first direction;
semiconductor channel layers spaced apart from each other and stacked on the active pattern in a direction perpendicular to an upper surface of the substrate;
a gate structure on the substrate, extending in a second direction, intersecting the semiconductor channel layers, and respectively surrounding the semiconductor channel layers; and
a source/drain region disposed on the active pattern on at least one side of the gate structure and respectively connected to the semiconductor channel layers,
wherein the gate structure respectively surrounds the semiconductor channel layers and includes a gate insulating layer and a gate electrode disposed on the gate insulating layer, and
wherein the gate insulating layer includes an interfacial insulating layer, a lower high-κ dielectric layer containing a first metal element, a composite dielectric layer containing the first metal element and a second metal element different from the first metal element, and an upper high-κ dielectric layer containing the second metal element, sequentially disposed on each of the semiconductor channel layers.

17. The semiconductor device of claim 16, wherein the gate insulating layer has a thickness of 40 Å or less.

18. The semiconductor device of claim 16, wherein the first metal element includes at least one of hafnium and zirconium, and
wherein the second metal element includes at least one of aluminum, hafnium, zirconium, and lanthanum.

19. The semiconductor device of claim 18, wherein:
the interfacial insulating layer includes silicon oxide or silicon oxynitride,
the lower high-κ dielectric layer includes hafnium oxide,
the composite dielectric layer includes an oxide containing hafnium and aluminum, and
the upper high-κ dielectric layer includes aluminum oxide.

20. A semiconductor device comprising:
a substrate including a first region and a second region;
a first active pattern on the first region of the substrate;
a first gate insulating layer including a first interfacial insulating film, a first lower high-κ dielectric film, and a first composite dielectric film, sequentially stacked on the first active pattern;
a first gate electrode on the first gate insulating layer;
a second active pattern on the second region of the substrate; and
a second gate insulating layer including a second interfacial insulating film, a second lower high-κ dielectric film, a second composite dielectric film, and a second upper high-κ dielectric film, sequentially stacked on the second active pattern, wherein:
each of the first and the second lower high-κ dielectric films includes a first metal element,
the second upper high-κ dielectric film includes a second metal element, and
each of the first and the second composite dielectric films includes both of the first and the second metal elements.

21-26. (canceled)
